(19) United States
(12) Patent Application Publication
(10) Pub. No.: US 2007/0273389 A1
(43) Pub. Date: Nov. 29, 2007

(54) Apparatus and method for processing a signal under test using a trigger signal synchronous with the signal under test for arbitrary impedance loads

(76) Inventors: Kan Tan, Beaverton, OR (US); John J. Pickerd, Hillsboro, OR (US)

Correspondence Address: THOMAS F. LENIHAN;TEKTRONIX, INC., 14150 S. W. KARL BRAUN DRIVE, P.O. BOX 500 (50-LAW), BEAVERTON, OR, 97077-0001, US

(21) Appl. No.: 11/442,517

(22) Filed: May 25, 2006

(51) Int. Cl. G01R 27/04

(52) U.S. Cl. 324/638

(57) ABSTRACT

A method and apparatus adapted to calibrate a test probe and oscilloscope system such that digital samples acquired by the system are processed for representing an arbitrary impedance loading of the device under test. The method and apparatus calibrates the test probe to characterize transfer parameters of the device under test within a spectral domain. A reflection coefficient ( [symbol] _{L}) is defined representative of an arbitrary impedance load coupled to the device under test and an equalization filter is computed to represent the loading of the device under test by the arbitrary impedance. Additional acquired samples are acquired using the equalization filter to effect thereby a representation of the arbitrary impedance loading of the device under test.

### FIELD OF THE INVENTION

The invention relates generally to signal acquisition systems and, more particularly, to a system, apparatus and method for processing acquired digital samples of a test signal from device under test using a trigger signal synchronous with the signal under test for producing digital samples representing an arbitrary impedance loading of the device under test

### BACKGROUND OF THE INVENTION

Typical probes used for signal acquisition and analysis devices such as digital storage oscilloscopes (DSOs) and the like have an impedance associated with them which varies with frequency. For example, a typical probe may have an impedance of 100K to 200K Ohms at DC, which impedance drops towards 200 ohms at 1.5 GHz. Higher bandwidth probes drop to even lower impedance values. This drop in impedance as frequency increases, coupled with the fact that many circuits being probed have a relatively low output impedance in the range of 25-150 ohms, results in a significant loading of the circuit under test by the probe. As such, an acquired waveform received via a probe loading such a circuit may not accurately represent the voltage of the circuit prior to the introduction of the probe.

There is also a further need to process acquired samples of a signal from a device under test to produce digital samples representing an arbitrary load on the device under test. Such a capability in a signal analysis system would allow a user to observe the effects of various loads on an output signal from the device under test.

### SUMMARY OF INVENTION

These and other deficiencies of the prior art are addressed by the present invention of a system, apparatus and method for processing acquired digital samples of a signal under test from a device under test for producing digital samples representing an arbitrary impedance loading of the device under test. Briefly, the invention provides a method to calibrate a probe and oscilloscope system by characterizing transfer parameters of the device under test within a spectral domain and in conjunction with a defined reflection coefficient representative of an arbitrary impedance load coupled to the device under test to produce an equalization filter adapted to represent the loading of the device under test by the arbitrary impedance. The equalization filter may be implemented in the frequency domain or the time domain. The signal from the device under test is passed through the equalization filter in either the frequency domain or the time domain with the frequency domain representation being transformed to the time domain. As a result, the user will see a time domain display that represents the signal in a circuit under test as it would appear with the arbitrary loading.

Specifically, a signal analysis system according to one embodiment of the invention has a digitizing instrument having a memory for storing transfer parameters associated with the digitizing instrument and generating digital samples of a signal under test with the digitizing instrument receiving a trigger signal synchronized to the signal under test. A test probe provides the signal under test from a device under test to the digitizing instrument. The test probe has a memory for storing transfer parameters associated with the probe. A controllable impedance device having selectable impedance loads is selectively coupled to the device under test. A controller having associated memory is coupled to receive the digital samples of the signal under test and communicates with the digitizing instrument and the test probe for selectively coupling impedance loads in the controllable impedance device to the device under test. The acquired time domain digital samples of the signal under test are converted to a spectral domain representation for each selected impedance load by the controller and the transfer parameters of the device under test within a spectral domain are characterized from the spectral domain representations for each selected impedance load. The controller computes an equalization filter using the characterized transfer parameters of the device under test and a reflection coefficient representative of an arbitrary impedance load coupled to the device under test.

A method according to one embodiment of the invention acquires a plurality of samples in the time domain a signal under test from a device under test via a signal path including a plurality of selectable impedance loads with the signal under test synchronized to a trigger signal. The plurality of time domain samples are converted to a spectral domain representation for each selected impedance load of the plurality of impedance loads. Transfer parameters of the device under test are characterized within a spectral domain from the spectral domain representation for each of the selected impedance loads. A reflection coefficient representative of an arbitrary impedance load coupled to the device under test is defined and an equalization filter adapted to represent the loading of the device under test by the arbitrary impedance is computed. The equalization filter is computed in the frequency domain but is convertible to time domain using well known frequency to time transformation techniques. Samples from device under test are acquired via a signal path not including the selectable impedance loads, and are either converted to the frequency domain for processing by the frequency domain equalization filter or processed directly by the time domain equalization filter to effect thereby a representation of the arbitrary impedance loading of the device under test.

### BRIEF DESCRIPTION OF THE DRAWINGS

The teachings of the present invention can be readily understood by considering the following detailed description in conjunction with the accompanying drawings, in which

FIG. 1 depicts a high level block diagram of a testing system including a device under test arranged in accordance with an embodiment of the present invention;

FIG. 2 depicts a high level block diagram of a signal analysis system;

FIG. 3 depicts a high level block diagram of a probe normalization fixture suitable for use in the system of FIG. 1;

FIG. 4 depicts an exemplary two-port model of a probe normalization test channel;

FIG. 5 depicts a flow diagram of a method for characterizing transfer parameters of a device under test according to an embodiment of the invention;

FIG. 6 illustrates one embodiment of a probe usable with the present invention;

FIG. 7 depicts a user interface screen suitable for use in an embodiment of the present invention;

FIG. 8 illustrates a device under test coupled to an arbitrary load for describing an embodiment of the present invention;

FIG. 9 depicts a flow diagram of a method according to an embodiment of the present invention;

FIG. 10A depicts a user interface screen suitable for use in an embodiment of the present invention;

FIG. 10B depicts a setup user interface screen suitable for use in an embodiment of the present invention; and

FIG. 10C depicts a further setup user interface screen suitable for use in an embodiment of the present invention.

To facilitate understanding, identical reference numerals have been used, where possible, to designate identical elements that are common to the figures.

### DETAILED DESCRIPTION OF THE INVENTION

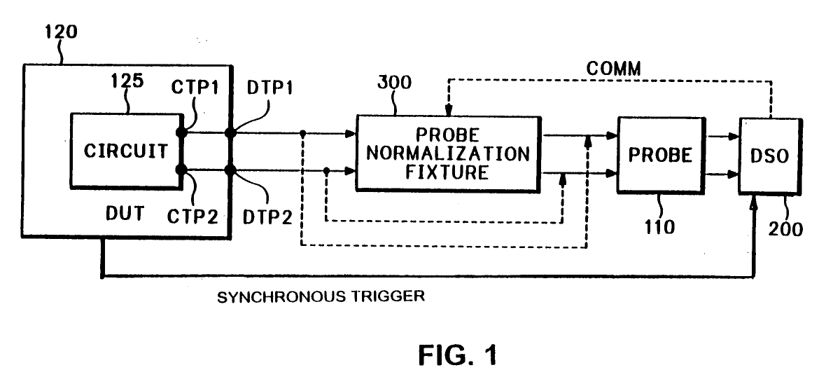

FIG. 1 depicts a high level block diagram of a testing system including a device under test arranged in accordance with an embodiment of the present invention. Specifically, a probe 110 is operably coupled to a signal analysis device such as a DSO 200 to provide thereto a signal under test (SUT) received from a device under test (DUT) 120. Interposed between the DUT 120 and the probe 110 is a probe normalization fixture 300.

In a calibrate mode of operation, the signal path between the DUT 120 and probe 110 passes through the probe normalization fixture 300. In a non-calibration mode of operation, a signal path between the DUT 120 and probe 110 is direct and excludes the probe normalization fixture 300. The calibration mode signal path is indicated by an unbroken line, while the non-calibration mode signal path is indicated by a dotted line. It will be noted that the probe paths depicted in FIG. 1 comprise two probe paths such as used within the context of a differential probe. In alternate embodiments, a single-ended or non-differential probe is used in which a first path passes a signal under test while a second path is operatively coupled to a common or ground point. Generally speaking, the normalization fixture is adapted to enable characterization of the device under test using switchable loads in the probe normalization fixture 300 such that an equalization filter may be computed. The equalization filter may be implemented in either the time domain or the frequency domain to be described in greater detail below. Upon removal of the normalization fixture from the signal path between the DUT 120 and probe 110, the equalization filter may be used to process the acquired samples from the DUT such that signal degradation or artifacts imparted to the SUT provided by the DUT are compensated for within the system, effectively de-embedding the loading of the DUT by the test and measurement system. If the relative time constants between the DUT 120 and the switchable loads in the normalization test fixture 300 are small, then the group delay of the signal under test has a minimal effect on the accuracy of the computed equalization filter when triggering the DSO 200 with the signal under test. In other cases, a synchronous trigger signal isolated from the SUT is preferably provided to a external trigger input of the DSO 200 from the DUT 120. The synchronous trigger signal assures that the DSO receives a trigger signal that is not affected by group delays of the SUT during calibration. The synchronous trigger signal may also be generated by an external trigger source that is synchronous with the SUT.

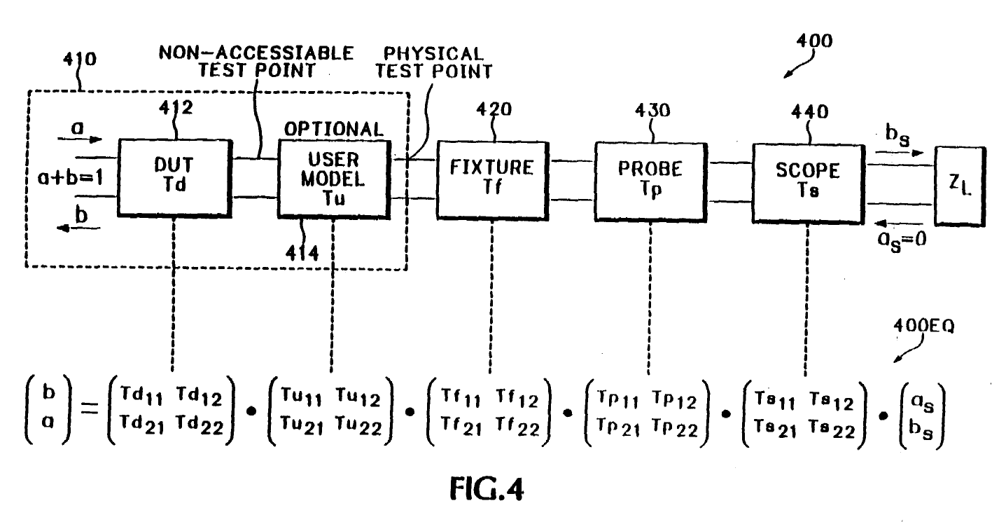

The (illustratively two) probe paths are coupled to the DUT 120 at a first device test point DTP1 and a second device test point DTP2. Optionally, internal to the DUT 120 is a circuit 125. The circuit 125 includes a first circuit test point CTP1 and a second circuit test point CTP2, where CTP1 is coupled to DTP1 and CTP2 is coupled to DTP2. For example, the DUT 120 may comprise an integrated circuit (IC) having a plurality of pins including pins associated with the test points DTP1 and DTP2, while a die within the IC includes the circuit test points CTP1 and CTP2. The difference in these tests points and the characterization of the operating parameters associated with these test points will be discussed in more detail below with respect to FIG. 4.

The invention operates to calibrate the probe 110 and, optionally, DSO input channel to remove (i.e., de-embed) their respective signal degrading effects from the measurement of the DUT (or circuit). This de-embedding process is conducted by characterizing the probe and other elements using a two-port S-parameter or T-parameter representation, which representation may be used to adjust impedance normalization parameters within the probe normalization fixture 300 and/or filter parameters used to process an acquired sample stream within the DSO 200

Optionally, a user may insert a mathematical model such as a two-port S-parameter or T-parameter representation into the signal measurement path to compensate for signal degradations or characteristics between the scope probe tip and the specific measurement point of a device under test. In this manner, an integrated circuit (IC) may be probed at its respective test point to provide, with mathematical compensation of the signal path between the test points (e.g., DTP1, DPT2) and the die interface (e.g., CTP1, CTP2), a voltage or signal for analysis that accurately represents the signal at the die itself. Generally speaking, the invention may utilize transfer parameters received from, e.g., the user that characterize a circuit between the test probe and the DUT such that the calculations of an equalization filter and the like are further adapted to compensate for loading of the DUT caused by the circuit between the probe and said DUT. Such insertion of additional transfer parameters is also useful in determining the effect of different intermediate circuitry (i.e., between a DUT or DUT portion and test probe) such as different die layout, packaging, DUT output circuitry and the like.

In one embodiment, the invention comprises a probe tip fixture that is inserted between a test probe and a device under test (DUT) and used during a one button press calibration procedure. This calibration procedure uses the signal under test provided by the device under test. The probe test fixture contains multiple loads (resistive and/or reactive impedances) that are selected based on the probe and in response to the device under test or signal produced by the device under test. The multiple loads comprise series, parallel and/or series/parallel combinations of resistive, capacitive and/or inductive elements. The multiple loads may be passive or active and may be selected using relays, solid state switching devices, or other selecting means. The probe tip fixture may comprise a stand-alone unit adapted to receive the probe or may be incorporated into the probe itself.

In one embodiment, the multiple loads are arranged as a load or impedance matrix. In various embodiments, the invention provides a new method and associated probe normalization fixture that allows the effects of probing to be de-embedded from the measurement of a device under test.

The invention utilizes a two-port matrix of S-parameters or T-parameters to model each element associated with the measurement signal path. Optionally, some elements are not modeled. The T-parameters are used so that a two-port matrix for each of the elements of the system model may be computed in a straight forward manner by multiplying them in the order they occur in the signal path. T-parameters are transfer parameters and are derived from S-parameters.

T-parameters for the normalization fixture and/or probe may be stored in the fixture itself, the probe or the DSO. In one embodiment, T-parameters for the probe are stored in the probe while T-parameters for the fixture are stored in the fixture. The scope channel T-parameters are optionally stored in the DSO 200.

The signal provided by the DUT is used as the signal source for a calibration procedure. The scope collects measurements with each of at least some of the loads in the fixture and then computes the T-parameters for the DUT. Once this is known, the fixture is removed and the probe is connected to the calibrated test point in the DUT. A correction equalization filter based on the calibration is then applied to the acquired data such that the effects of probe loading as a function of frequency are removed or offset. The entire calibration process is automated and activated from, for example, a single menu button in the oscilloscope. It should be noted that the fixture may be left in place after the calibration process to improve accuracy by avoiding physical movement of the probing fixture (since slight changes in position can affect the calibration).

The relationship between S- and T-parameters will now be briefly discussed. It should be noted that while T-parameters are primarily described within the context of the invention, the use of S-parameters instead of T-parameters is also contemplated by the inventors. Thus, S-parameters may be substituted wherever the storage and/or use of T-parameters is discussed herein. T-parameters may be computed from the S-parameters at the time the algorithms are processed. The relationship between T- and S-parameters is given by equations 1 and 2 below:

$$\begin{matrix}( \begin{matrix}{T}_{11} & {T}_{12} \\ {T}_{21} & {T}_{22}\end{matrix} ) = ( \begin{matrix}- \frac{{S}_{11} {S}_{22} - {S}_{12} {S}_{21}}{{S}_{21}} & \frac{{S}_{11}}{{S}_{12}} \\ - \frac{{S}_{22}}{{S}_{21}} & \frac{1}{{S}_{21}}\end{matrix} ) & ( EQ 1 ) \\ ( \begin{matrix}{S}_{11} & {S}_{12} \\ {S}_{21} & {S}_{22}\end{matrix} ) = ( \begin{matrix}\frac{{T}_{12}}{{T}_{22}} & \frac{{T}_{11} \cdot {T}_{22} - {T}_{12} \cdot {T}_{21}}{{T}_{22}} \\ \frac{1}{{T}_{22}} & \frac{- {T}_{21}}{{T}_{22}}\end{matrix} ) & ( EQ 2 )\end{matrix}$$

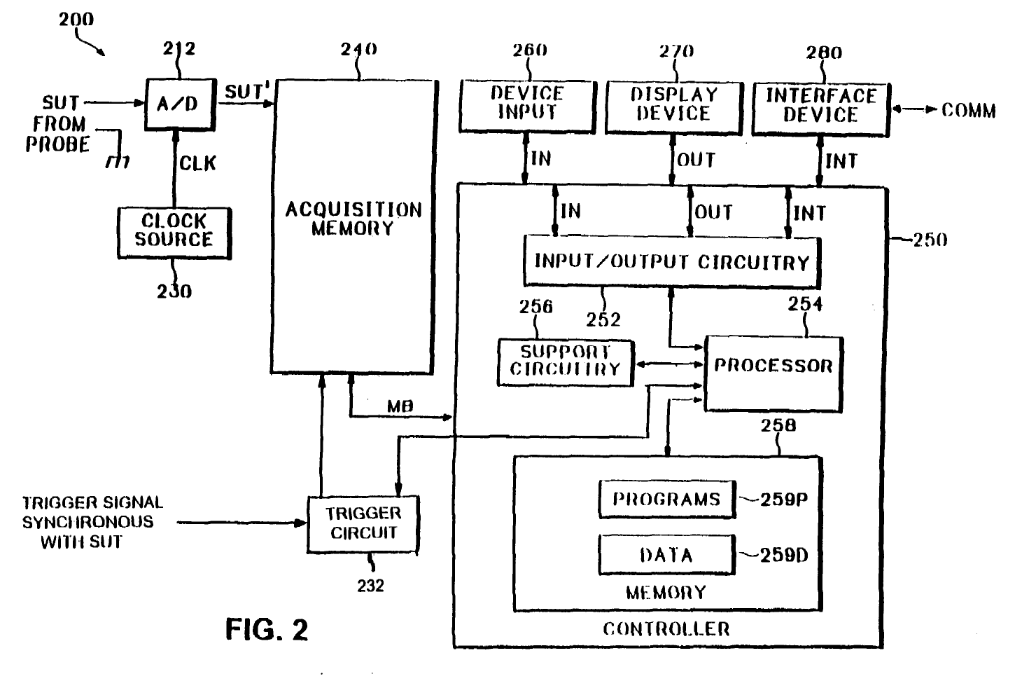

FIG. 2 depicts a high level block diagram of a signal analysis device such as a digital storage oscilloscope (DSO) suitable for use with the present invention. Specifically, the system (signal analysis device) 200 of FIG. 1 comprises an analog to digital (A/D) converter 212, a clock source 230, a trigger circuit 232, an acquisition memory 240, a controller 250, an input device 260, a display device 270 and an interface device 280. The A/D converter 212 receives and digitizes a SUT in response to a clock signal CLK produced by the clock source 230. The clock signal CLK is preferably a clock signal adapted to cause the A/D converter 212 to operate at a maximum sampling rate, though other sampling rates may be selected. The clock source 230 is optionally responsive to a clock control signal CC (not shown) produced by the controller 250 to change frequency and/or pulse width parameters associated with the clock signal CLK. It is noted that the A/D converter 212 receives the SUT via a probe (not shown), which probe may comprise a differential probe or a single ended (i.e., non-differential) probe.

A digitized output signal SUT′ produced by the A/D converter 212 is stored in the acquisition memory 240. The acquisition memory 240 cooperates with the controller 250 to store the data samples provided by the A/D converter 212 in a controlled manner such that the samples from the A/D converter 212 may be provided to the controller 250 for further processing and/or analysis.

The controller 250 is used to manage the various operations of the system 200. The controller 250 performs various processing and analysis operations on the data samples stored within the acquisition memory 240. The controller 250 receives user commands via an input device 260, illustratively a keypad or pointing device. The controller 250 provides image-related data to a display device 270, illustratively a cathode ray tube (CRT), liquid crystal display (LCD) or other display device. The controller 250 optionally with a communications link COMM, such as a general purpose interface bus (GPIB), Internet Protocol (IP), Ethernet or other communications link via the interface device 280. It is noted that the interface device 280 is selected according to the particular communications network used. An embodiment of the controller 250 will be described in more detail below.

The signal analysis device 200 is set-up by user commands from the input device 260 that established a trigger threshold and pre and post trigger times for the storing of the digital samples from the A/D converter 212. The digital samples are initially stored in a circular buffer in the acquisition memory. The circular buffer continuously stores digital samples from the A/D converter 212 with new digital samples overwriting older digital samples once the circular buffer is full. The synchronous trigger signal is received by the trigger circuit 232 which generates a trigger output to the acquisition memory upon the synchronous trigger signal crossing the trigger threshold to stop the storing of digital samples in the circular buffer after the post trigger time. The contents of the circular buffer are stored as a waveform record within the acquisition memory 240.

The system 200 of FIG. 2 is depicted as receiving only one SUT. However, it will be appreciated by those skilled in the art that many SUTs may be received and processed by the system 200. Each SUT is preferably processed using a respective A/D converter 212, which respective A/D converter may be clocked using the clock signal CLK provided by common or respective clock source 230 or some other clock source. Each of the additional digitized SUTs is coupled to the acquisition memory 240 or additional acquisition memory (not shown). Any additional acquisition memory communicates with the controller 250, either directly or indirectly through an additional processing element.

The controller 250 comprises a processor 254 as well as memory 258 for storing various programs 259P (e.g., calibration routines) and data 259D (e.g., T- and/or S-parameters associated with one or more components within the testing system). The processor 254 cooperates with conventional support circuitry 256 such as power supplies, clock circuits, cache memory and the like, as well as circuits that assist in executing the software routines stored in the memory 258. As such, it is contemplated that some of the process steps discussed herein as software processes may be implemented within hardware, for example as circuitry that cooperates with the processor 254 to perform various steps. The controller 250 also contains input/output (I/O) circuitry 252 that forms an interface between the various functional elements communicating with the controller 250. For example, the controller 250 communicates with the input device 260 via a signal path IN, a display device 270 via a signal path OUT, the interface device 280 via a signal path INT and the acquisition memory 240 via signal path MB. The controller 250 may also communicate with additional functional elements (not shown), such as those described herein as relating to additional channels SUT processing circuitry, switches, decimators and the like. It is noted that the memory 258 of the controller 250 may be included within the acquisition memory 240, that the acquisition memory 240 may be included within the memory 258 of the controller 250, or that a shared memory arrangement may be provided.

Although the controller 250 is depicted as a general purpose computer that is programmed to perform various control functions in accordance with the present invention, the invention can be implemented in hardware as, for example, an application specific integrated circuit (ASIC). As such, the process steps described herein are intended to be broadly interpreted as being equivalently performed by software, hardware or a combination thereof.

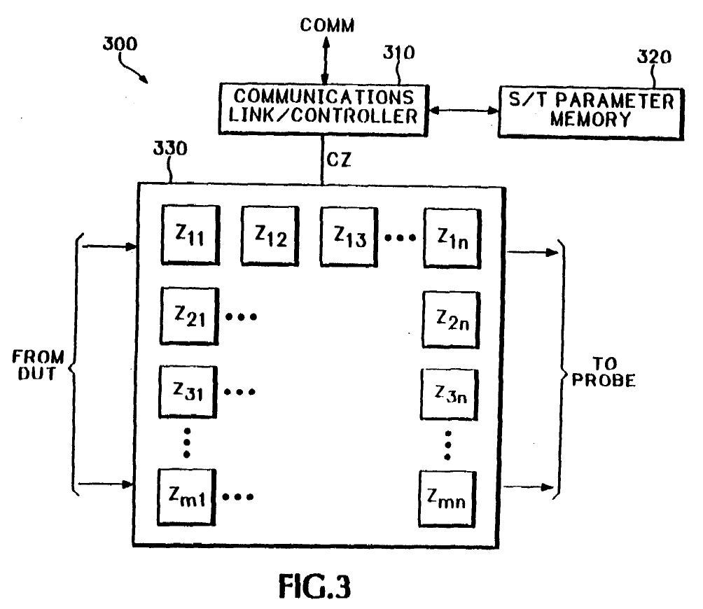

FIG. 3 depicts a high level block diagram of a probe normalization fixture suitable for use in the system of FIG. 1. Specifically, the probe normalization fixture 300 of FIG. 3 comprises a communication link/controller 310, an S- or T-parameter memory 320 and a selectable impedance matrix 330. The S/T parameter memory 320 is used to store S- or T-parameters associated with the probe 110 and, optionally, any of the DUT 120, circuit 125, DSO 200 or user supplied parameters. The parameters stored in the memory 320 are provided via, illustratively, the communication link/control circuit 310. The communication link/control circuit 310 is operatively coupled to a signal analysis device (e.g., a DSO), a computer (not shown) or other test system controller via a communication link COMM, illustratively an Ethernet, Universal Serial Bus (USB) or other communication link. The communication link/control circuit 310 also controls the selectable impedance matrix 330 via a control signal CZ.

The selectable impedance matrix 330 comprises a plurality of impedance elements Z arranged in matrix form. Specifically, a first impedance element in a first row is denoted as Z₁₁, while the last impedance element in the first row is denoted as Z₁ₙ. Similarly, the last impedance element in a first column is denoted as Zₘ₁, while the last impedance in the nth column is denoted as Zₘₙ. While depicted as an m×n grid or matrix of selectable impedance elements, it will be noted that a more simplified array of impedance elements may be provided. It is also noted that each of the impedance elements may comprise a resistive element, a capacitive element, an inductive element and any combination of active or passive impedance elements. The impedance matrix 330 may provide serial, parallel, serial and parallel or other combinations of passive or active impedances to achieve the purpose of impedance normalization between the DUT (or circuit) and probe 110.

Generally speaking, the purpose of the impedance element matrix 330 is to adapt the input impedance of the probe 110 to the output impedance of the DUT 120 (or circuit 125) such that undue loading of the measured signal parameters is avoided or at least reduced, while there is enough signal passed into probe. At the same time various load ranges must be provided so that adequate DUT loading occurs to provide good signal to noise ratio for the calibration procedure. The impedance matrix may be modified to provide additional normalization. That is, rather than normalizing just the probe 110, the probe normalization fixture 300 may also be used to normalize the probe 110 in combination with the input channel of the DSO 200 utilizing the probe 110. Various other permutations will be recognized by those skilled in the art and informed by the teachings of the present invention.

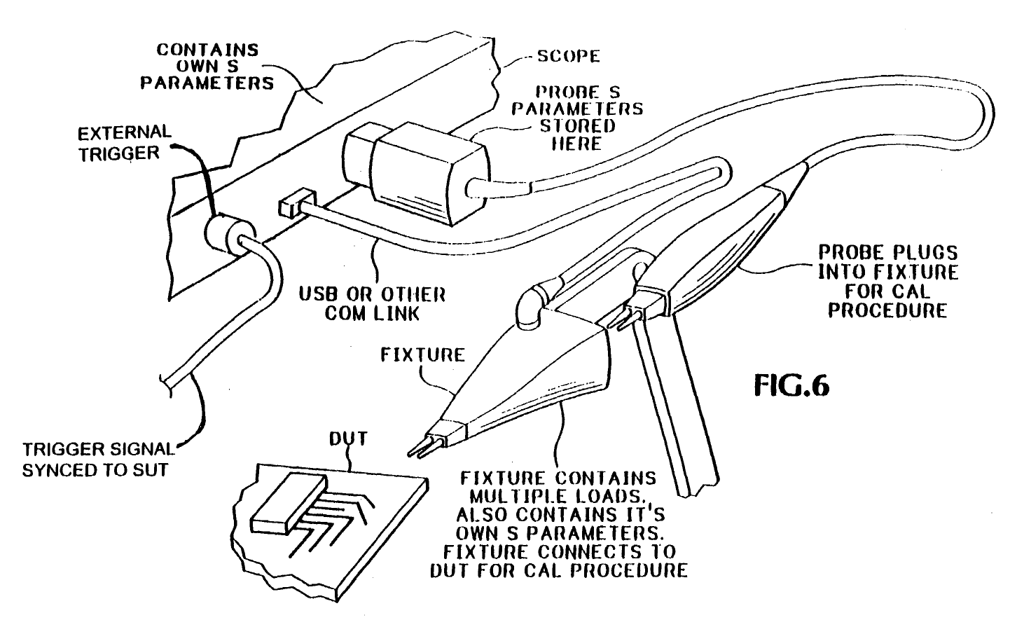

The probe normalization fixture may be a stand alone unit or incorporated within the probe 110. Generally speaking, the probe normalization fixture 300 comprises a set of input probe pins adapted for connection to the DUT and a set of output probe pins adapted for connection to the probe 110. In the case of the probe normalization fixture 300 being included within the probe 110, an electronic or mechanical selection means may be employed within the probe 110 to facilitate inclusion or exclusion of the probe normalization fixture function from the circuit path between the DUT and probe. An embodiment of the probe normalization fixture will be discussed in further detail below with respect to FIG. 6.

The S/T parameter memory 320 may comprise a non-volatile memory where S- or T-parameters for fixture loads are stored. These S- or T-parameters may be provided to an oscilloscope or computer via the communications link COMM such that additional processing may be performed within the signal analysis device. In one embodiment, the probe normalization fixture 300 has associated with it a plurality of probe tips adapted for use by, for example, different devices under test, different testing programs and the like (e.g., current probes, voltage probes, high-power probes and the like). Each of these probe tips may be characterized by respective T-parameters or S-parameters, which T-parameters or S-parameters may be stored in the memory 320 of the probe normalization fixture 300. In one embodiment, the communications link/controller 310 detects the type of probe tip attached and responsively adapts the T- or S-parameters within the memory 320. Thus, the T-parameters or S-parameters associated with specific probe tips of the normalization fixture may be included within the set of equations describing the testing circuit. The T-parameters or S-parameters associated with one or more probe tips may be stored in memory within the probe, the probe tip, the oscilloscope or the fixture.

FIG. 4 depicts an exemplary two-port model and corresponding equations of a probe normalization test channel in which a plurality of elements within the test and measurement system are modeled as a series connection of T-parameter 2-port networks. Specifically, the model 400 (and corresponding equations 400EQ) of FIG. 4 comprises a device under test 2-port network 410 (denoted as Td), a fixture 2-port network 420 (denoted as Tf), a probe 2-port network 430 (denoted as Tp) and a scope 2-port network 440 (denoted as Ts). The DUT 2-port network 410 is depicted as including a DUT network 412 (Td) and a user model 414 (denoted as Tu).

The user model 2-port network 414 (Tu) is optionally provided and gives a T-parameter model for part of the hardware of a device under test. For example, the user model 414 may be used to represent the operating characteristics of a portion of a between an accessible portion (i.e., where probes are operably coupled) to a desired test portion that is normally inaccessible within the DUT (i.e., a portion on the edge of or within a die). The user model accommodates this by letting the user load the S-parameter model (or T-parameter model) into, for example, the DSO, where it becomes part of the calibration process. For example, if the user knows the S-parameters for a bond wire connection from an IC pin to a die chip, then the T-parameter model of the connection may be included in the calculations as the Tu matrix. After system calibration, a probe of the IC pin will result in a waveform representing the die chip signal level.

In general, the invention operates to obtain a frequency domain result by using an FFT transform of the measured incident signal, bₛ, for each calibration load in the fixture. After the final vₒₚₑₙ is computed the result is transformed back to the time domain by using an IFFT. In one embodiment, a filter is employed to implement the FFT and/or IFFT operations.

For illustrative purposes, several assumptions will be made. For initial derivations, the DUT 2-port model will be assumed to have input incidence signal of “a” and a reflected signal of “b”, where “a” and “b” are normalized such that a+b=1. The Td, user DUT, will have internal signal and this results in what will be called the normalized Td parameters. It is assumed the measurement system will be modeled as a series of S-parameter two port networks, which will be converted to T-, transfer, parameters for ease of matrix solutions. These two port networks represent the user's circuit under test and are ordered (per FIG. 4 and equation 3) left to right as DUT, User DUT Model, Fixture, Probe, and Oscilloscope.

In order to simplify the measurement equations it will be assumed that the frequency response of the scope and it's input connector is flat enough. It will also be assumed that the input voltage to port model Td is a+b, and that a+b is a constant voltage source internal to the Td circuit at it's input port. It will also be assumed that scope input and connector provides a relatively flat 50 ohm impedance match over the relevant bandwidth. However, other versions of the measurement may also take into account the parameters of the scope response. This does not preclude the possibility that the scope T-parameters would also be included in the normalization. It is also possible that an assumption of aₛ equal zero at the two-port output of the S-parameter model for the scope might be made.

$$( \begin{matrix}b \\ a\end{matrix} ) = ( \begin{matrix}{Td}_{11} & {Td}_{12} \\ {Td}_{21} & {Td}_{22}\end{matrix} ) \cdot ( \begin{matrix}{Tu}_{11} & {Tu}_{12} \\ {Tu}_{21} & {Tu}_{22}\end{matrix} ) \cdot ( \begin{matrix}{Tf}_{11} & {Tf}_{12} \\ {Tf}_{21} & {Tf}_{22}\end{matrix} ) \cdot ( \begin{matrix}{Tp}_{11} & {Tp}_{12} \\ {Tp}_{21} & {Tp}_{22}\end{matrix} ) \cdot ( \begin{matrix}{Ts}_{11} & {Ts}_{12} \\ {Ts}_{21} & {Ts}_{22}\end{matrix} ) \cdot ( \begin{matrix}{a}_{s} \\ {b}_{s}\end{matrix} ) \qquad Equation 3$$

### Where:

Td is the transfer parameters of the DUT;
Tu is a user model of part of circuit under test;
Tf is the transfer parameters of the probe test fixture;
Ts is the transfer parameters of the oscilloscope;
Tp is the transfer parameters of the probe;
bₛ is the voltage measured at the DSO output; and
aₛ is the reflected voltage at the DSO output (assumed to be zero for this derivation, though other derivations and implementation may include it).

Considering the assumptions that a+b=1 and aₛ=0, EQ 3 can be re-written as follows:

$$( \begin{matrix}1 & 1\end{matrix} ) ( \begin{matrix}b \\ a\end{matrix} ) = ( \begin{matrix}1 & 1\end{matrix} ) ( \begin{matrix}{Td}_{11} & {Td}_{12} \\ {Td}_{21} & {Td}_{22}\end{matrix} ) \cdot ( \begin{matrix}{Tu}_{11} & {Tu}_{12} \\ {Tu}_{21} & {Tu}_{22}\end{matrix} ) \cdot ( \begin{matrix}{Tf}_{11} & {Tf}_{12} \\ {Tf}_{21} & {Tf}_{22}\end{matrix} ) \cdot ( \begin{matrix}{Tp}_{11} & {Tp}_{12} \\ {Tp}_{21} & {Tp}_{22}\end{matrix} ) \cdot ( \begin{matrix}{Ts}_{11} & {Ts}_{12} \\ {Ts}_{21} & {Ts}_{22}\end{matrix} ) \cdot ( \begin{matrix}0 \\ {b}_{s}\end{matrix} ) \qquad Equation 3 A$$

such that:

$$1 = a + b = ( \begin{matrix}{Td}_{1} & {Td}_{2}\end{matrix} ) \cdot ( \begin{matrix}{Tu}_{11} & {Tu}_{12} \\ {Tu}_{21} & {Tu}_{22}\end{matrix} ) \cdot ( \begin{matrix}{Tf}_{11} & {Tf}_{12} \\ {Tf}_{21} & {Tf}_{22}\end{matrix} ) \cdot ( \begin{matrix}{Tp}_{11} & {Tp}_{12} \\ {Tp}_{21} & {Tp}_{22}\end{matrix} ) \cdot ( \begin{matrix}{Ts}_{11} & {Ts}_{12} \\ {Ts}_{21} & {Ts}_{22}\end{matrix} ) \cdot ( \begin{matrix}0 \\ {b}_{s}\end{matrix} ) \qquad Equation 3 B$$

where:

Td₁=Td₁₁+Td₂₁

Td₂=Td₁₂+Td₂₂ (EQ 3C)

It should be noted that a different set of Tf for each of the loads switched onto the DUT. The values of Tf, and Tp are measured at time of manufacture and stored in the probe and fixture respectively. The values of Td are computed by making a measurement of bₛ with each of the loads of Tf and then solving the appropriate set of equations. The test setup requires that test fixture connect to the DUT and that probe connects into test fixture.

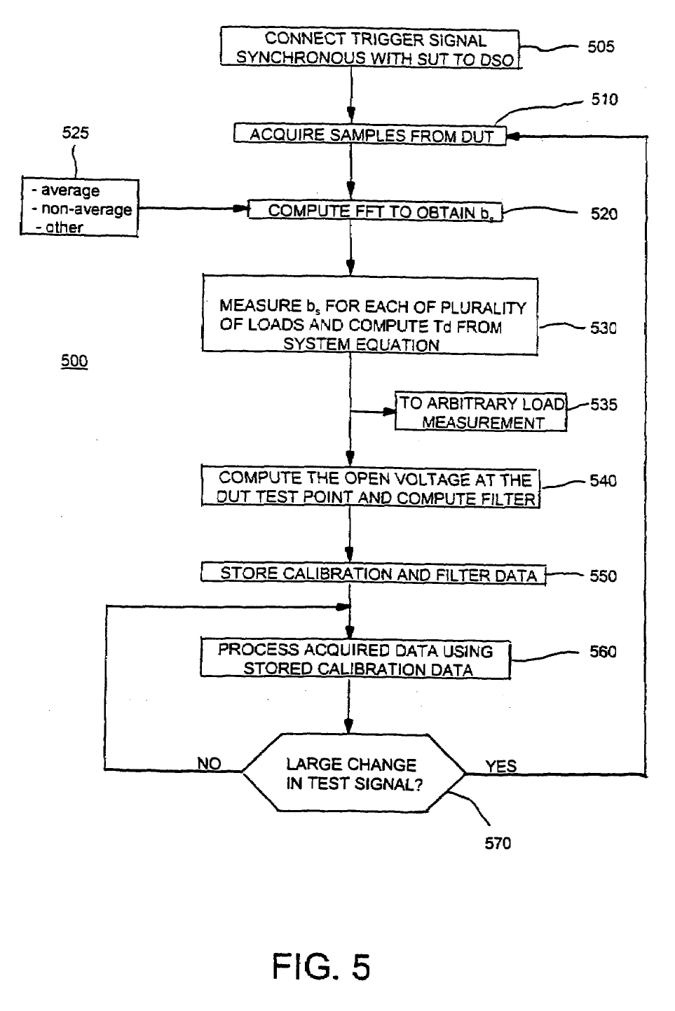

FIG. 5 depicts a flow diagram of a method for generating the S- or T-parameters of the DUT and an equalization filter for representing an open voltage at the probe test point. The method 500 of FIG. 5 is suitable for use in, for example, the system 100 of FIG. 1. The method utilizes the two port model discussed above and assumes that the signal under test provided by the DUT is a relatively steady-state signal (i.e., relatively stable or repeating spectral and/or time domain energy distribution). The equations discussed herein with respect to FIG. 5 (and other figures) depict a plurality of two-port representations including device under test, user, normalization fixture, probe and/or scope T-parameters. The invention may be practiced using only the device parameters Td, fixture parameters Tf and probe parameters Tp where method and apparatus according to the invention are adapted for compensating for the loading imparted to a device under test by a probe. The addition of the scope T-parameters Ts and/or user parameters Tu may be employed in various embodiments. Thus, equations provided herein may be utilized without the user (Tu) and/or scope (Ts) parameters.

The method 500 is entered at step 505, where a trigger signal synchronous with the signal under test is coupled to an external trigger input of the signal analysis device 200. At step 510, time domain samples of the signal under test are acquired from the DUT. At step 520, a Fast Fourier Transform (FFT) is computed to obtain the obtain bₛ. Referring to box 525, the computation may be performed using averaged or non-averaged data.

At step 530, bₛ is measured and Td is computed for each of a plurality of load selections (within the normalization fixture). Td is computed using (for the exemplary embodiment), the following equations:

$$\begin{matrix}1 = ( \begin{matrix}{Td}_{1} & {Td}_{2}\end{matrix} ) \cdot ( \begin{matrix}{Tu}_{11} & {Tu}_{12} \\ {Tu}_{21} & {Tu}_{22}\end{matrix} ) \cdot ( \begin{matrix}Tf {1}_{11} & Tf {1}_{12} \\ Tf {1}_{21} & Tf {1}_{22}\end{matrix} ) \cdot ( \begin{matrix}{Tp}_{11} & {Tp}_{12} \\ {Tp}_{21} & {Tp}_{22}\end{matrix} ) \cdot ( \begin{matrix}{Ts}_{11} & {Ts}_{12} \\ {Ts}_{21} & {Ts}_{22}\end{matrix} ) \cdot ( \begin{matrix}0 \\ {b}_{s}\end{matrix} ) & Equation 4 \\ 1 = ( \begin{matrix}{Td}_{1} & {Td}_{2}\end{matrix} ) \cdot ( \begin{matrix}{Tu}_{11} & {Tu}_{12} \\ {Tu}_{21} & {Tu}_{22}\end{matrix} ) \cdot ( \begin{matrix}Tf {2}_{11} & Tf {2}_{12} \\ Tf {2}_{21} & Tf {2}_{22}\end{matrix} ) \cdot ( \begin{matrix}{Tp}_{11} & {Tp}_{12} \\ {Tp}_{21} & {Tp}_{22}\end{matrix} ) \cdot ( \begin{matrix}{Ts}_{11} & {Ts}_{12} \\ {Ts}_{21} & {Ts}_{22}\end{matrix} ) \cdot ( \begin{matrix}0 \\ {b}_{2 s}\end{matrix} ) & Equation 5 \\ 1 = ( \begin{matrix}{Td}_{1} & {Td}_{2}\end{matrix} ) \cdot ( \begin{matrix}{Tu}_{11} & {Tu}_{12} \\ {Tu}_{21} & {Tu}_{22}\end{matrix} ) \cdot ( \begin{matrix}Tf {3}_{11} & Tf {3}_{12} \\ Tf {3}_{21} & Tf {3}_{22}\end{matrix} ) \cdot ( \begin{matrix}{Tp}_{11} & {Tp}_{12} \\ {Tp}_{21} & {Tp}_{22}\end{matrix} ) \cdot ( \begin{matrix}{Ts}_{11} & {Ts}_{12} \\ {Ts}_{21} & {Ts}_{22}\end{matrix} ) \cdot ( \begin{matrix}0 \\ {b}_{3 s}\end{matrix} ) & Equation 6\end{matrix}$$

To solve for the variables Td₁ and Td₂, two equations obtained from measurements with two different loads are sufficient. However, the inventors note that multiple equations from multiple measurements using different loads can improve the accuracy of Td₁ and Td₂ values by, for example, simple averaging or minimum least square error methods. Once the variables Td₁ and Td₂ are solved, the voltage at the DUT test point may be determined for an arbitrary impedance load to be discussed in greater detail below.

At step 540, the open voltage at the DUT probe point is calculated by replacing the two-port network with a two-port representation of an open circuit, as follows:

$$1 = ( \begin{matrix}{Td}_{1} & {Td}_{2}\end{matrix} ) \cdot ( \begin{matrix}1 & 0 \\ 0 & 1\end{matrix} ) \cdot ( \begin{matrix}{a}_{0} \\ {b}_{0}\end{matrix} ) \qquad ( EQ 7 )$$

The inventors note that the open circuit voltage vₒₚₑₙ is actually twice the value of aₒ since in the open circuit case aₒ=bₒ and vₒₚₑₙ=aₒ+bₒ, such that:

$${v}_{open} = 2 {a}_{0} = \frac{2}{{Td}_{1} + {Td}_{2}} \qquad ( EQ 8 )$$

In one embodiment of the invention, at step 540 the equations are derived from the above measurements to realize a frequency domain filter response. The frequency domain response of the filter can be derived from its transfer function. The filter transfer function is as follows:

$$H = \frac{{v}_{open}}{{b}_{is}} \qquad ( EQ 9 )$$

such that:

\hat{v}ₒₚₑₙ=H·\hat{b}ₛ (EQ 10)
where bᵢₛ is the scope measurement i-th load during calibration procedure, and bₛ is the scope measurement with the same i-th load during testing procedure.

The above response is then multiplied with an FFT of each new time domain acquisition with the probe at a test point to provide thereby a de-embedded response at the DUT test point. Thus, the T parameters for the DUT (and, optionally, corresponding parameters for the normalization fixture, probe and/or scope) are determined such that an equalization filter based upon the various parameters with the normalization fixture removed may be determined. This filter is applied after the normalization fixture is removed from the circuit and the scope probe is connected to the same point in the DUT where the fixture calibration process was performed. In this manner, the normalization fixture is used to characterize the loading of the system upon the device under test and such that an equalization filter may be provided wherein such device loading is compensated for. Alternatively, the fixture may be left in place without perturbing the physical positions for better de-embed accuracy. The filter is then applied to the FFT of the acquired signal. An inverse FFT of \hat{v}ₒₚₑₙ yields the time domain version of this signal.

In a further embodiment of the invention, the frequency domain equalization filter H is converted to a time domain equalization filter using well known transformation techniques, such as an inverse FFT, inverse DFT and the like. The time domain equalization filter is then convolved with each new time domain acquisition with the probe at a test point to provide thereby a de-embedded response at the DUT test point. At step 550, the calibration data and, optionally, filter data is stored in, for example, the data portion 259D of the memory 258. It is noted that in the above solution (EQ 8), the term aₒ represents the voltage in the DUT probe point with substantially all effects of probing de-embedded. This is the desired result of the calibration process. As a practical matter, it is noted that the physical movement of a probe (especially a non-differential probe) will slightly perturb the characteristics and, therefor, a new calibration might be desired. Alternatively, the fixture may be left in place without perturbing the physical positions for better de-embed accuracy.

At steps 560 and 570 the method operates to repeatedly process acquired data using the stored calibration data to provide de-embedded data for generating waveforms, providing test data to remote devices and the like. Upon detecting (at step 570) a relatively large change in the test signal, the method proceeds to step 510. For example, in one embodiment of the invention, during calibration the changes in measured voltages as a function of frequency for various loads connected is noted by the controlling device (e.g., a DSO). The controlling device then chooses only those loads that give minimal change in DUT voltage while still providing enough change to have a reasonable signal to noise ratio for the de-embed computations.

In one embodiment of the invention, once calibration has been performed and the DUT signal is being observed with de-embedding, the user is alerted if a major difference in the signal occurs in terms of signal level or waveshape. In an alternate embodiment, another calibration is performed for this case so that the user can make determinations of circuit linearity based on signal level. For example if the DUT signal was calibrated with one level and then changed to another amplitude level then the user measures the new level with the current calibration. Then the user optionally performs a new calibration and measure this signal again. If the measured results are different between the two calibrations then that would be an indication of non-linear DUT behavior at different signal levels.

In still another embodiment, where the user knows the S- or T-parameters of a particular test point, those test parameters are loaded into the testing or controlling device via, for example, the above-described menu structure. In this embodiment, there is no need to connect the de-embed fixture, and the probe is directly connected to the test point.

New data bₛ is acquired and now the values of aᵢₙ and bᵢₙ are computed as shown in the following equation:

$$( \begin{matrix}{b}_{in} \\ {a}_{in}\end{matrix} ) = ( \begin{matrix}{Td}_{11} & {Td}_{12} \\ {Td}_{21} & {Td}_{22}\end{matrix} ) \cdot ( \begin{matrix}{Tu}_{11} & {Tu}_{12} \\ {Tu}_{21} & {Tu}_{22}\end{matrix} ) \cdot ( \begin{matrix}{Tp}_{11} & {Tp}_{12} \\ {Tp}_{21} & {Tp}_{22}\end{matrix} ) \cdot ( \begin{matrix}{Ts}_{11} & {Ts}_{12} \\ {Ts}_{21} & {Ts}_{22}\end{matrix} ) \cdot ( \begin{matrix}0 \\ {b}_{2}\end{matrix} ) \qquad ( EQ 11 )$$

Once aᵢₙ and bᵢₙ are known, then the probe two-port matrix can be replaced with an open circuit two-port representation, identity matrix, and the DUT test point voltage can computed as 2aₒₚₑₙ, as follows:

$$( \begin{matrix}{b}_{in} \\ {a}_{in}\end{matrix} ) = ( \begin{matrix}{Td}_{11} & {Td}_{12} \\ {Td}_{21} & {Td}_{22}\end{matrix} ) \cdot ( \begin{matrix}1 & 0 \\ 0 & 1\end{matrix} ) \cdot ( \begin{matrix}{a}_{open} \\ {b}_{open}\end{matrix} ) \qquad ( EQ 12 )$$

### As previously noted, an IFFT of aₒₚₑₙ is computed to obtain the time domain version of the signal under test.

FIG. 6 illustrates one embodiment of the present invention. Specifically, FIG. 6 graphically illustrates an embodiment of the invention wherein a scope (optionally storing S-parameters and/or T-parameters) is operatively coupled to a probe. The scope receives a trigger signal synchronized to the SUT via a external trigger input jack. The probe optionally stores S-parameters and/or T-parameters in, for example, a non-volatile memory within the probe connector housing. A normalization fixture containing multiple loads and/or an impedance matrix such as described above with respect to FIG. 3 is adapted to receive the probe at an input. The normalization fixture is also adapted to receive a communication link from the scope. The normalization fixture optionally stores its own S-parameters and/or T-parameters. The normalization fixture includes a probe tip adapted to electrically probe a device under test, such as described above with respect to the various figures. It should be noted that the separate communication link cable between the normalization fixture and the scope shown in FIG. 6 may be integrated with the probe cable. It should also be noted that the function of the normalization fixture may be included within the probe.

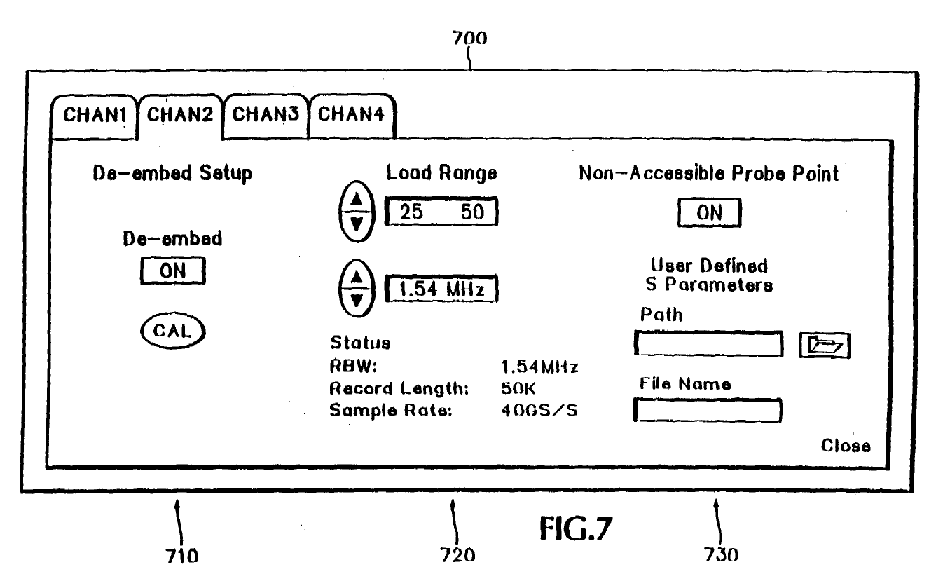

FIG. 7 depicts a user interface screen suitable for use in an embodiment of the present invention. Specifically, FIG. 7 depicts a de-embed set-up menu 700 comprising de-embed selector commands 710, load range commands 720 and non-accessible probe point commands 730. The de-embed set-up menu 700 may be accessed directly or via other menus (not shown) within the menu structure or hierarchy of a digital storage oscilloscope, computer or other test and measurement device.

Referring to the de-embed set-up commands 710, a first button denoted as “ON” is used to enable or disable the de-embed function, while a second button denoted as “CAL” is used to enable calibration of a test system according to the system, method and apparatus discussed above. That is, assuming the de-embed function is enabled, a calibration function is utilized wherein a probe is connected to a normalization fixture, the normalization fixture is connected to a device under test, the calibration button is pressed, and the resulting waveforms are viewed after processing according to, for example, the method described above with respect to FIG. 5.

The load range functions 720 allow user selection of a range of DUT load impedance (illustratively 25-50 ohms) via a first dialog box and a resolution bandwidth (RBW, illustratively 1.54 MHz) via a second dialog box. A status box provides an indication to a user of, illustratively, a bandwidth range, a record length (illustratively 50 KB) and a sample rate (illustratively 40 GS/s). Other information may be included within the status indication box.

Referring to the non-accessible probe point command 730, a first button denoted as “ON” enables the use of user defined S- or T-parameters within the context of the present invention. That is, where a user wishes to incorporate the S- or T-parameters associated with a two-port network mathematically inserted between the DUT and normalization fixture two-port networks (or other location), those S- or T-parameters are provided by the user as a file. Thus, the non-accessible probe point commands include a path dialog box enabling the user to identify where within the mass storage structure of the DSO the files are located, and a file name dialog box indicating the name of the user supplied S- or T-parameter file.

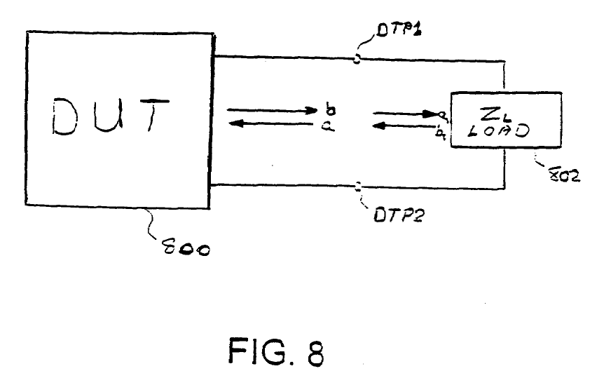

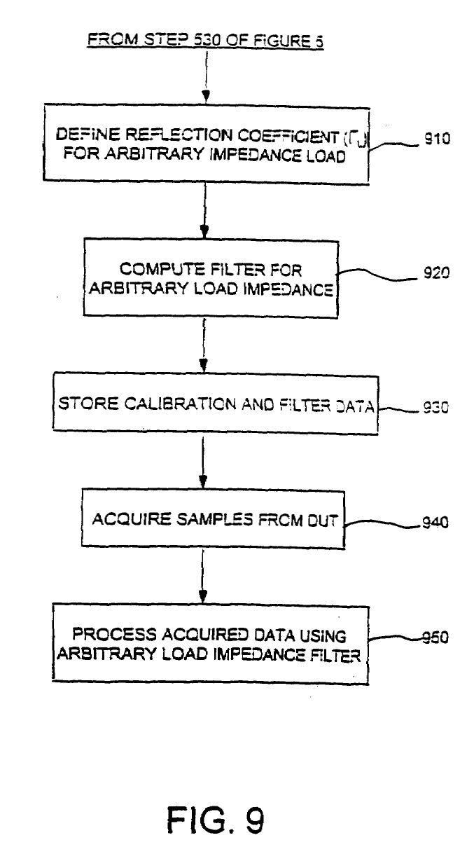

Once the initial measurements have been made and the characterizing equations determined for the T- or S-parameters of the DUT as represented in steps 510 through 530 in FIG. 5, a computation may be made to determine what the DUT test voltage would look like with an arbitrary load (Z_{L}) as represented in step 535. FIG. 8 is a representation of a DUT 800 connected to an arbitrary load (Z_{L}) 802. The voltage out of the DUT 800 into the DUT test point DTP1 is “b” and the reflected voltage from the DUT test point DTP2 to the DUT 800 is “a”. The incident voltage “a,” from the DUT test point DTP1 and the reflected voltage “b₁” into the DUT test point DPT2 are related to the DUT as:

$$1 = [ \begin{matrix}{Td}_{1} & {Td}_{2}\end{matrix} ] \cdot [ \begin{matrix}{b}_{1} \\ {a}_{1}\end{matrix} ] \qquad ( EQ 13 )$$

where Td₁ and Td₂ are combinations of the T-parameters of the DUT described with relation to the calibration of the probe. When the DUT is connected to an arbitrary load (Z_{L}) 802, loading can be represented by its reflection coefficient ( [symbol] _{L}) where “a₁” and “b₁” are related by b₁= [symbol] _{L}·a₁ where the reflection coefficient is the S₁₁ parameter of the arbitrary load. The reflection coefficient for the arbitrary load 802 may be specified by the user using the equation:

$${L}_{} = \frac{{Z}_{L} - {Z}_{ref}}{{Z}_{L} + {Z}_{ref}} \qquad ( EQ 14 )$$

where Z_{ref} is known and Z_{L} is the impedance of the arbitrary load as represented by step 910 in the flow diagram of FIG. 9. In the preferred embodiment of the invention, Z_{ref} is the characteristic impedance of the measurement system which is generally 50 ohms but other impedance values may be used without departing from the scope of the present invention.

The total voltage V_{L} at the test points DTP1 and DTP2 is the sum of the incident voltage and the reflected voltage as shown by the following equation.

V_{L}=a₁+b₁ (EQ 15)

At step 920, the voltage at the test points DTP1 and DTP2 with a load can be derived from the previous equations and written as follows:

$${V}_{L} = \frac{{L}_{} + 1}{{Γ}_{L} {Td}_{1} + {Td}_{2}} \qquad ( EQ 16 )$$

With the transfer parameters Td₁ and Td₂ known from the probe calibration and the reflection coefficient of the arbitrary load Z_{L} provided by the user, a frequency domain equalization filter may be realized having a transfer function as follows:

$$H ( f ) = \frac{{V}_{L}}{{b}_{is}} \qquad ( EQ 17 )$$

such that:

\hat{v}_{L}=H·\hat{b}ₛ (EQ18)
where bᵢₛ is the scope measurement i-th load during calibration procedure, and \hat{b}ₛ is the scope measurement with the same i-th load during testing procedure.

At step 930, the calibration data from steps 510 through 530, and optionally, filter data for the arbitrary impedance load is stored in, for example, the data portion 259D of the memory 258. The frequency domain equalization filter H(f) may be converted to a time domain equalization filter H(t) using well known transformation techniques, such as an inverse FFT, inverse DFT and the like. At 940 and 950, the above filter response is then convolved with each new acquisition with the probe at the test points DTP1- and DTP2 to provide a representation of the arbitrary impedance 802 loading of the DUT 800 for generating waveforms, providing test data to remote devices and the like. Alternately, the frequency domain equalization filter may be multiplied with frequency domain representations of the time domain acquisitions to provide a frequency domain representation of the arbitrary impedance 802 loading of the DUT 800. The frequency domain representations of the time domain acquisitions to provide a frequency domain representation of the arbitrary impedance 802 is converted to a time domain representation using well known transformation techniques, such as an inverse FFT, inverse DFT and the like. Using the arbitrary impedance load invention, a user may examine the signal at the DUT probe point with various arbitrary impedance loads to observe the effects of loads on the signal. For example, an arbitrary load equal to a measurement system reference impedance Z_{ref} of 50 ohms would have a reflection coefficient ( [symbol] _{L}) of 0 where equation 16 would yield:

$${V}_{Zref} = \frac{1}{{Td}_{2}} \qquad ( EQ 19 )$$

where V_{Zref} is the voltage at the test points DTP1 and DTP2 terminated by the reference impedance.

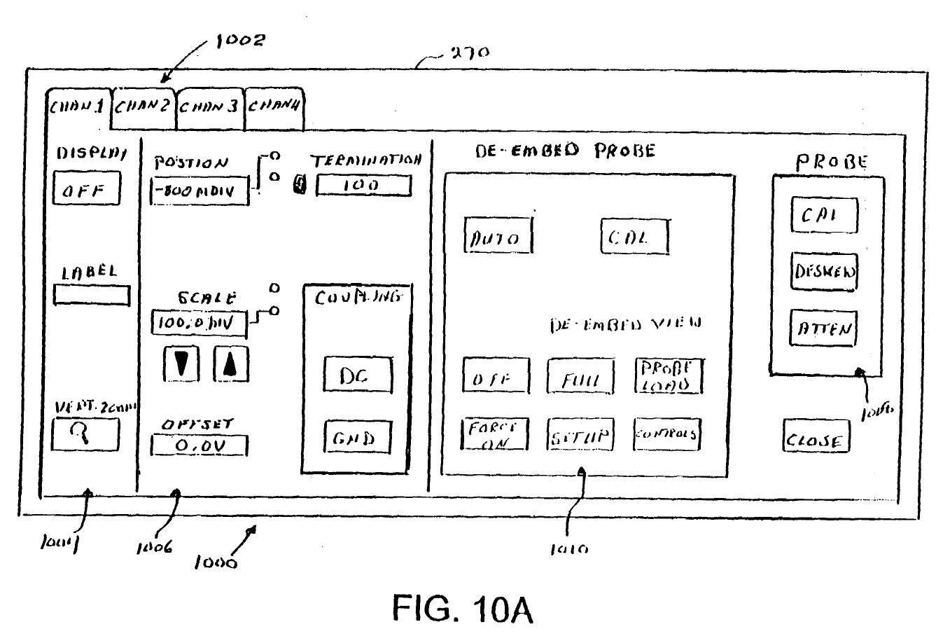

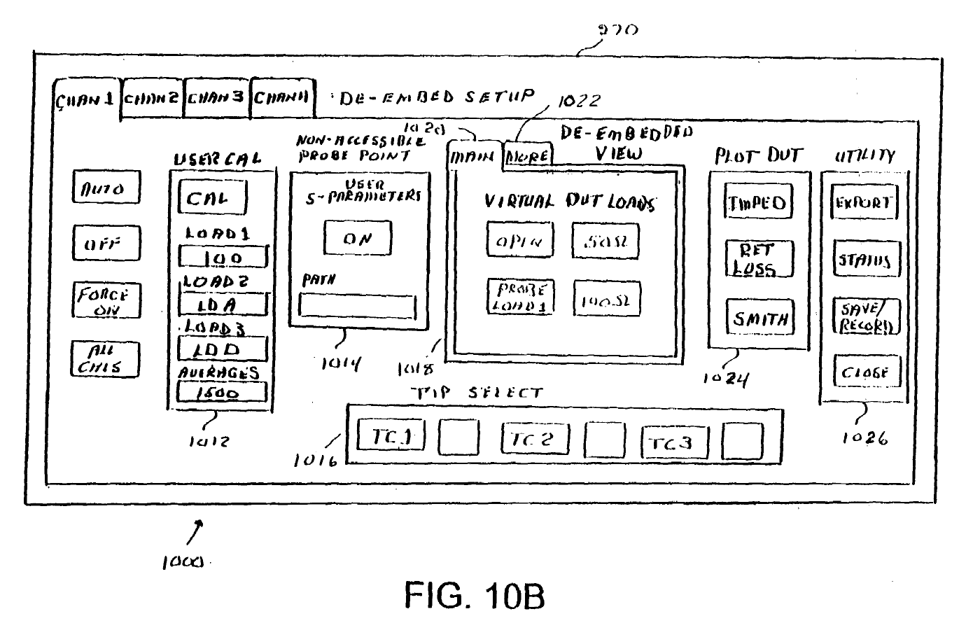

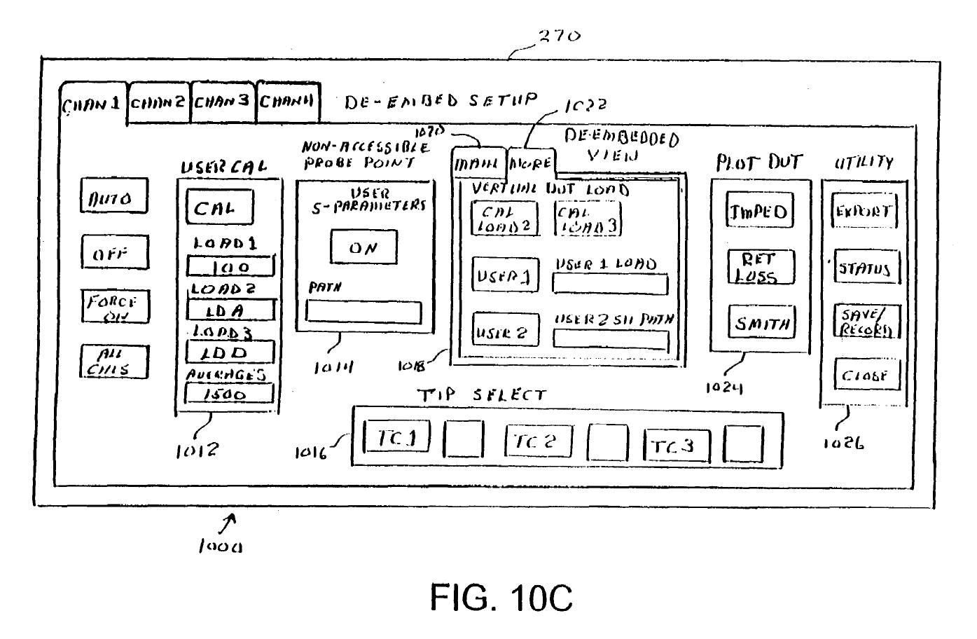

FIG. 10A illustrates an example of a user interface 1000 for implementing the arbitrary impedance load testing system and method of the present invention. The user interface 1000 may be implemented as part of the vertical menu on a TDS6804B Digital Phosphor Oscilloscope, manufactured and sold by Tektronix, Inc. Beaverton, Oreg. The user interface 1000 is displayed on the display device 270 under control of the controller 250. The user interface has channel tabs 1002 for each of th respective channels of the oscilloscope 200. The controller 250 detects the presence of probe capable of being de-embedded and configures the user interface 1000 accordingly. The user interface 1000 is divided into sections with section 1004 related to display parameters and section 1006 related to the channel conditioning parameters. Section 1008 relates to selectable probe procedures, such as a standard probe calibration procedure, a procedure for deskewing multiple probes coupled to the oscilloscope, and a procedure for setting the probe attenuation. Section 1010 relates to the parameters and procedures for de-embedding the probe.

The CAL menu button is pressed by the user after the probe has been connected to the DUT 800. A pop-up dialog box having FINISH and CANCEL button may be included to prompt the user to make sure the probe is connected to the DUT 800. The calibration process applies de-embed loads to the DUT 800 test points DTP1 and DTP2 and calculates the combination of S- or T-parameters Td₁ and Td₂ of the DUT 800. The AUTO button turns on the de-embed filter operations, such as full de-embed and the arbitrary load testing, as long as the scope parameters allows it. The OFF button turns off the de-embed filter operation resulting the acquired samples having errors due to the probe loading and through response and due to the oscilloscope response. Various parameter setting for the oscilloscope may cause the filter not to run. The FORCE ON button addresses this issue by changing the oscilloscope parameter setting to allow the de-embed filter to run. The FULL de-embed view configures the filter operation to process the acquired samples as if the DUT 800 is coupled to an open load. The PROBE LOAD de-embed view configures the filter operation to process the acquired samples as if the DUT 800 is coupled a probe having its associated impedance. The SETUP button brings up a display of a de-embed setup menu that contains additional controls for configuring the de-embed probe

FIG. 10B illustrates an example of a de-embed setup menu. On the left side of the display are the AUTO, OFF and FORCE on buttons previously described. The all channels ALL CHLS button when activated will force the AUTO/OFF/FORCE ON functions to occur on all channels that have a de-embed probe connected. THE USER CAL section 1012 of the display includes the CAL button previously described and fields for defining the de-embed loads that are to be used when the CAL process is executed. LOAD 1, LOAD2 and LOAD3 allow the user to specify the de-embed cal loads that are used during calibration. Alternately, the system may be configured to automatically set specified de-embed cal loads. The AVERAGES field specifies the number of averages used for the signal acquisitions during the CAL process. The NON-ACCESSIBLE PROBE POINT section 1014 includes an ON/OFF button and a field for entering a path to a two-port S- or T-parameter file defining the characteristics of a portion of the DUT 800 between the probe test points DTP1 and DPT2 and the circuit test points CTP1 and CTP2. With the ON/OFF button on, the two-port S- or T-parameter file is included in the calibration of the probe. The TIP SELECT section 1016 of the display allows a user to specify a particular probing tip that is to be connected to the probe. The oscilloscope has a library of S- or T-parameters for the available probing tips. Type numbers identify the probing tips and the display may include pictures of the tips to allow the user to be sure that the selected tip matches the selected parameters.

The DE-EMBEDDED VIEW section 1018 has a MAIN tab 1020 and a MORE tab 1022. The MAIN tab 1020 displays buttons that activate various virtual DUT loads. The OPEN button activates the de-embed filter that results in a full de-embed (i.e. an equalization filter representing an open load on the DUT). The loading effects of the probe, the through response of the probe and scope are removed from the acquired samples of the DUT signal. The PROBE LOAD 1 button activates a de-embed filter that results in the acquired samples representing the DUT signal with the probe loading the DUT signal. The error due to the probe through response and the oscilloscope response are removed from the acquired samples. The 50Ω and 100Ω buttons respectively activate de-embed filters that results in the acquired samples representing the DUT signal with a 50 ohm load and a 100 ohm load coupled to the DUT. The PLOT DUT section 1024 of the display has buttons that allows the user to activate display plots of the impedance, return loss, and a smith chart of the impedance derived from the acquired samples of the DUT signal. The Utility section 1026 of the display includes an EXPORT button that when activated brings up an export menu dialog box. The dialog box allows a user to specify a file name and export an ASCII file of the processed data from the DUT. The STATUS button activates a view window with information about the relevant parameters associated with the de-embed operation. The SAVE/RECORD button activates a submenu that allows the user to save the current DUT test point calibration data and filter to a file. It includes a field that allows the user to enter a name associated with each DUT test point.

FIG. 10C illustrates an example of the DE-EMBEDDED VIEW section 1018 where the MORE tab 1022 has been activated. The MORE tab 1022 displays buttons that activate additional virtual DUT loads. The CAL LOAD2 and CAL LOAD3 buttons respectively activate de-embed filters that results in the acquired samples representing the DUT signal with the CAL LOAD2 and the CAL LOAD3 loading the DUT signal. The USER1 button and associated field activates a de-embed filter having an arbitrary impedance load defined by the user. The load value may be specified as a single resistance element or a single reactive element or combination of the two. For example, an entry of 75 in the filed means 75 ohms resistance. A value of j85 means an inductive reactance of 85 ohms. A value of 35-j77 means a combination of a resistance of 35 ohms and capacitive reactance of 77 ohms. The USER2 button and associated filed activates a de-embed filter having an arbitrary impedance defined by an S- or T-parameter file and path. The S₁₁ parameter or its T-parameter equivalent would be contained in an ASCII format in a file provided by the user. This allows the user to specify a very complex load that varies as a function of frequency.

The present invention is a system and process that characterizes the transfer parameters of a device under test using acquired samples of the signal from a device under test, assigning an arbitrary impedance load to the device under test derived from a reflection coefficient, computing an equalization filter adapted to represent the loading of the device under test by the arbitrary impedance, and processing additional acquired samples using the equalization filter to effect thereby a representation of the arbitrary impedance loading of the device under test. The arbitrary impedance load may be a user assigned resistance value, reactance value, a combination of both, S- or T-parameters associated with the probe, oscilloscope, and S- or T-parameters files.

While the foregoing is directed to the preferred embodiment of the present invention, other and further embodiments of the invention may be devised without departing from the basic scope thereof. For example, the equations presented in the above specification are of a specific form and may be factored to other forms and still represent equivalent equations. Therefore, the scope of the present invention is determined by the claims that follow.

What is claimed is:

1. A method of processing a plurality of acquired samples of a signal under test from a device under test comprising the steps:
acquiring a plurality of samples in the time domain of the signal under test from the device under test via a signal path including a plurality of selectable impedance loads with the signal under test synchronized to a trigger signal;
converting the plurality of samples of the signal under test in the time domain to a spectral domain representation for each of the selected impedance loads of the plurality of impedance loads;
characterizing transfer parameters of the device under test within a spectral domain from the spectral domain representation for each selected impedance load of the plurality of impedance loads;
defining a reflection coefficient ( [symbol] _{L}) representative of an arbitrary impedance load coupled to the device under test; and
computing an equalization filter adapted to represent the loading of the device under test by the arbitrary impedance.

2. The method of processing a plurality of acquired samples from a device under test as recited in claim 1,
acquiring samples from device under test in the time domain via a signal path not including the selectable impedance loads with the signal under test synchronized to a trigger signal;
converting the samples in the time domain from the device under test to a spectral domain representation; and
processing the acquired samples using the equalization filter to effect thereby a representation of the arbitrary impedance loading of the device under test.

3. The method of processing a plurality of acquired samples from a device under test as recited in claim 1,
converting the computed equalization filter from the frequency domain to a time domain equalization filter;
acquiring samples from device under test in the time domain via a signal path not including the selectable impedance loads with the signal under test synchronized to a trigger signal; and
processing the acquired samples using the time domain equalization filter to effect thereby a representation of the arbitrary impedance loading of the device under test.

4. The method of processing a plurality of acquired samples of a signal under test from a device under test as recited in claim 1, wherein the step of characterizing the transfer parameters of the device under test comprises computing, for each of a plurality of load selections, parameters associated with two-port network representation of the following form:
$$1 = ( \begin{matrix}{Td}_{1} & {Td}_{2}\end{matrix} ) \cdot ( \begin{matrix}{Tu}_{11} & {Tu}_{12} \\ {Tu}_{21} & {Tu}_{22}\end{matrix} ) \cdot ( \begin{matrix}{Tfi}_{11} & {Tfi}_{12} \\ {Tfi}_{21} & {Tfi}_{22}\end{matrix} ) \cdot ( \begin{matrix}{Tp}_{11} & {Tp}_{12} \\ {Tp}_{21} & {Tp}_{22}\end{matrix} ) \cdot ( \begin{matrix}{Ts}_{11} & {Ts}_{12} \\ {Ts}_{21} & {Ts}_{22}\end{matrix} ) \cdot ( \begin{matrix}0 \\ {b}_{is}\end{matrix} )$$

5. The method of processing a plurality of acquired samples of a signal under test from a device under test as recited in claim 1, further comprising:
computing the reflection coefficient ( [symbol] _{L}) of an arbitrary impedance load at the device under test probe point using an equation of the following form:
$${Γ}_{L} = \frac{{Z}_{L} - {Z}_{ref}}{{Z}_{L} + {Z}_{ref}}$$

6. The method of processing a plurality of acquired samples of a signal under test from a device under test as recited in claims 5 further comprising:
computing a load voltage (V_{L}) at the device under test probe point using an equation of the following form:
$${V}_{L} = \frac{{L}_{} + 1}{{L}_{} {Td}_{1} + {Td}_{2}}$$

7. The method of processing a plurality of acquired samples of a signal under test from a device under test as recited in claim 6, wherein the load voltage \hat{v}_{L} is realized using an equalization filter having a transfer function of the following form:
$$H ( f ) = \frac{{V}_{L}}{{b}_{is}}$$
such that:
\hat{v}_{L}=H·\hat{b}ₛ
where bᵢₛ is the scope measurement i-th load during calibration procedure, and \hat{b}ₛ is the scope measurement with the same i-th load during testing procedure.

8. A signal analysis system for processing acquired digital samples of a signal under test from a device under test to represent an arbitrary load on the device under test comprising:
a digitizing instrument having a memory for storing transfer parameters associated with the digitizing instrument and acquiring time domain digital samples of a signal under test with the digitizing instrument receiving a trigger signal synchronized to the signal under test;
a test probe providing the incoming signal under test to the digitizing instrument, the test probe having associated with it a memory for storing transfer parameters associated with the probe, and a controllable impedance device having selectable impedance loads selectively coupled to the device under test; and
a controller having associated memory communicating with the digitizing instrument and the test probe for selectively coupling impedance loads in the controllable impedance device to the device under test and receiving the acquired time domain digital samples of the signal under test and converting the time domain digital samples to a spectral representation for each of the selected impedance loads, and characterizing the transfer parameters of the device under test within a spectral domain from the spectral domain representation for each selected impedance load, the controller computing load voltages (V_{L}) from the acquired digital samples of the signal under test at the device under test probe point using the characterized transfer parameters of the device under test and a reflection coefficient ( [symbol] _{L}) representative of an arbitrary impedance load coupled to the device under test.

9. The signal analysis system as recited in claim 8 further comprising addition memory for storing the digital samples of the signal under test and program control instructions for the controller.

10. The signal analysis system as recited in claim 8 further comprising a display device for displaying the computed load voltages (V_{L}) of the signal under test.

11. The signal analysis system as recited in claim 10 wherein the digitizing instrument further comprises a digital oscilloscope.

12. The signal analysis system as recited in claim 11 wherein the controller is disposed in the digital oscilloscope and controls the acquisition of the digital samples of the signal under test and the display of the computed load voltages (V_{L}).

13. The signal analysis system as recited in claim 8 wherein the transfer parameters of the digitizing instrument and the test probe comprise at least one of S-parameters and T-parameters.

14. The signal analysis system as recited in claim 8 wherein the reflection coefficient ( [symbol] _{L}) comprises a user defined load impedance.
